(19) United States
(12) Patent Application Publication
(10) Pub. No.: US 2018/0309009 A1
(43) Pub. Date: Oct. 25, 2018

(54) AGEING-RESISTANT ALUMINIUM CONNECTORS FOR SOLAR CELLS

(71) Applicant: Heraeus Deutschland GmbH & Co. KG, Hanau (DE)

(72) Inventors: Andreas Henning, Sinntal-Mottgers (DE); Markus Koenig, Dieburg (DE)

(21) Appl. No.: 15/933,530

(22) Filed: Mar. 23, 2018

(30) Foreign Application Priority Data
Apr. 19, 2017 (EP) 17166965.8

(51) Int. Cl. H01L 31/05; H01L 31/0232

(52) U.S. Cl. CPC H01L 31/0512; H01R 4/04; H01L 31/0508; H01L 31/02327

(57) ABSTRACT

The present invention relates to a connector for connecting a solar cell electrode to a further element, whereby the connector comprises a conductor pattern on which at least one metallic coating is arranged, whereby the conductor pattern contains aluminium, characterised in that the coating contains an element selected from the group consisting of Ni, Ag, Sn, Pb, Zn, Bi, In, Sb, Co, Cr as well as alloys of said elements.

The present invention relates to connectors for connecting a solar cell electrode to a further element, whereby the connector contains aluminium. The invention also relates to a photovoltaics component comprising a solar cell, in which the electrode of a solar cell is connected to a further element by means of the connector according to the invention.

A solar cell typically contains at least the following components: a semiconductor layer, which optionally comprises an additional doping (p- or n-type); at least one front electrode on the side on which the sunlight is incident on the solar cell and at least one rear electrode on the side away from the sunlight.

For many applications, individual solar cells are connected in series and are connected by means of a connector to form photovoltaics modules. In this context, a front electrode of a solar cell is connected to the rear electrode of a further solar cell by means of a connector.

Usually, copper ribbons are used to connect multiple solar cells by their electrodes to form photovoltaics modules. Said copper ribbons often comprise a solder coating that can be applied to the copper ribbons prior to the connecting. For example tin or tin-containing alloys can be used as solder materials for the coatings. Said solder-precoated copper ribbons are contacted to the electrodes of a solar cell and are soldered to each other by heating. This technology permits the production of highly conductive, mechanically robust connections between individual solar cells. Coating the copper ribbon with a solder material can afford additional protection against corrosion of the connector. Alternatively, known connectors are also connected to solar cells by means of conductive adhesives. Photovoltaics modules, in which individual solar cells are connected to copper connectors by means of an electrically conductive adhesive film, are known from EP2234180A2. Since the material costs of copper connectors are high, it is desirable to use connectors that are made of a less expensive material and comprise an electrical conductivity that is about as good as that of copper.

Due to its good electrical conductivity and the low material costs, aluminium has advantageous properties for the connection of electrical components, such as, e.g., silicon solar cells. Moreover, aluminium is not a precious metal and produces a native oxide layer on the surface. This oxide layer can passivate the metal and protect it from further corrosion by oxidation. Aluminium connectors have certain disadvantages as well though.

Photovoltaics modules consisting of multiple solar cells are often provided with a polymer protection layer. Said polymer protection layer often contains polyesters. Exposed to heat and moisture, said polyesters can release ingredients that have an acidic effect, such as, e.g., acetic acid.

In an acidic and moist environment, the aluminium connectors are often not sufficiently stable to corrosion despite the presence of a passivation layer. By and by, metallic aluminium is converted into aluminium oxide. Since aluminium oxide is electrically insulating, the corrosion reduces the conductivity of the aluminium connector and has a detrimental effect on the performance of the solar cell. The corrosion can be very disadvantageous especially at the contact surface of connector and solar cell electrode. Aluminium connectors, in which the aluminium is doped by elements such as Sc, Mg, and Zr, are known from US20150122378A1. Said doping is meant to improve the corrosion resistance of the connectors under acidic conditions.

Direct welding to the surface of the aluminium connector is not feasible, since the application of liquid solder is associated with the generation of a thin aluminium oxide layer on the connector that prevents the solder material from adhering sufficiently. This also impairs electrical contacting.

It was the object of the present invention to provide aluminium connectors for solar cells that are protected from corrosion and, at the same time, can connect solar cells to form modules in a mechanically stable manner.

It is another preferred object of the invention to provide connectors for solar cell electrodes that are designed appropriately such that the utilisation efficiency of the light that is incident on the solar cell is improved.

### DESCRIPTION OF THE INVENTION

In the figures illustrating the invention:

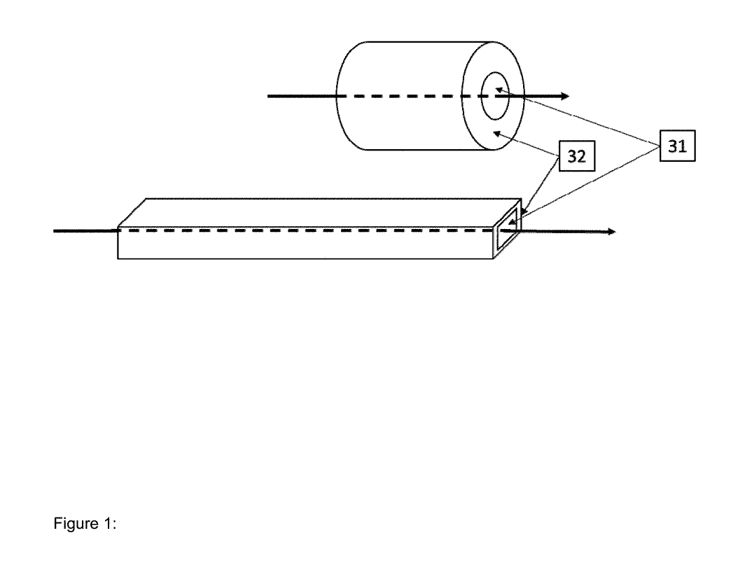

FIG. 1: shows a conductor pattern with metallic coating;

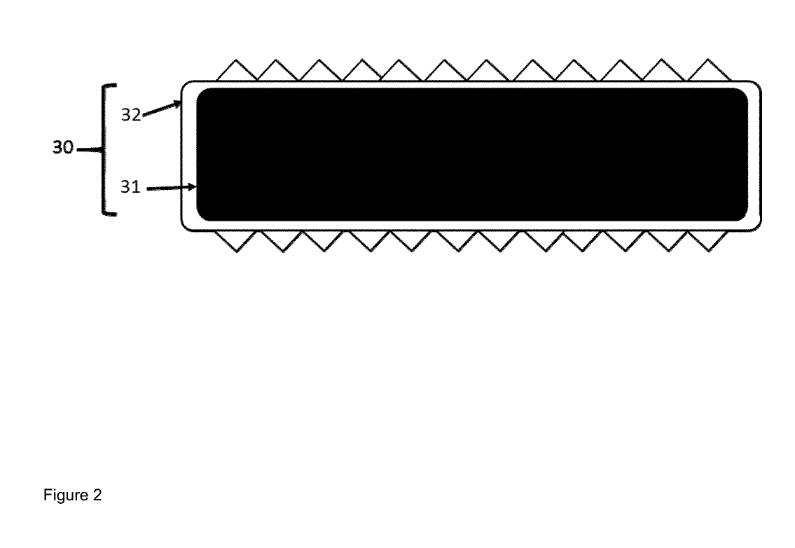

FIG. 2: shows a conductor pattern with metallic coating, whereby the coating comprises a pattern;

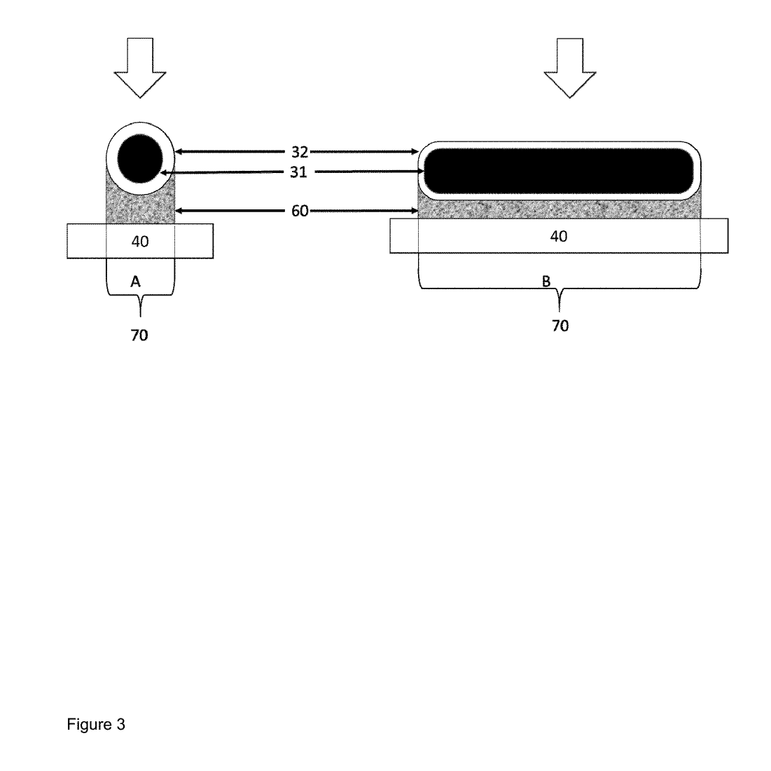

FIG. 3: shows the process of connecting the connector to a solar cell electrode via the entire perpendicular projection surface of the connector. The arrows indicate the direction perpendicular to the surface of the semiconductor layer;

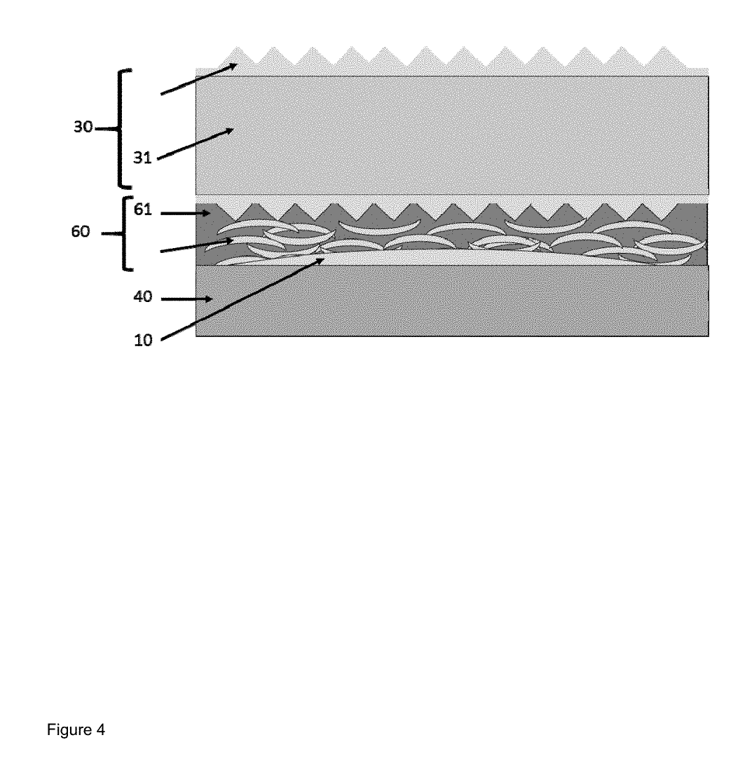

FIG. 4: shows an exemplary cross-section of the connection between connector and solar cell electrode in a photovoltaics module according to the invention;

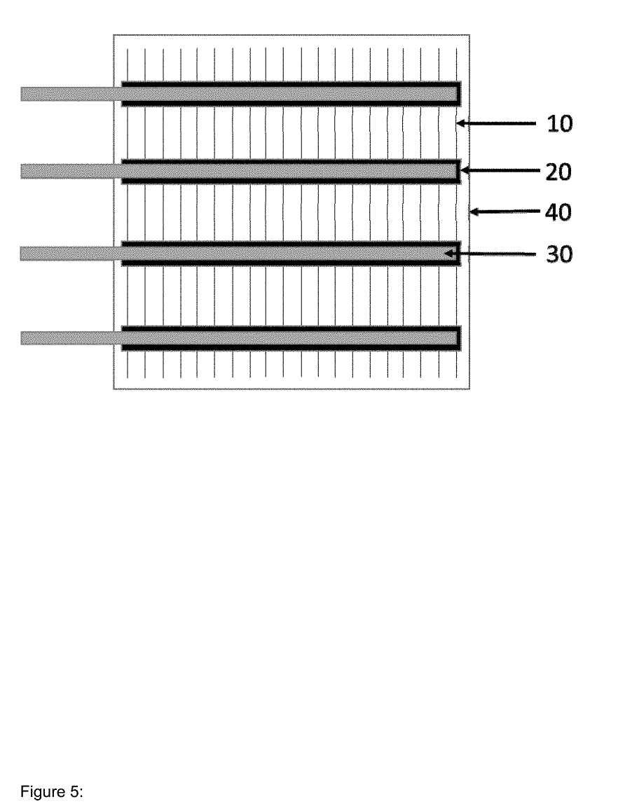

FIG. 5: shows a top view of a solar cell with connector; and

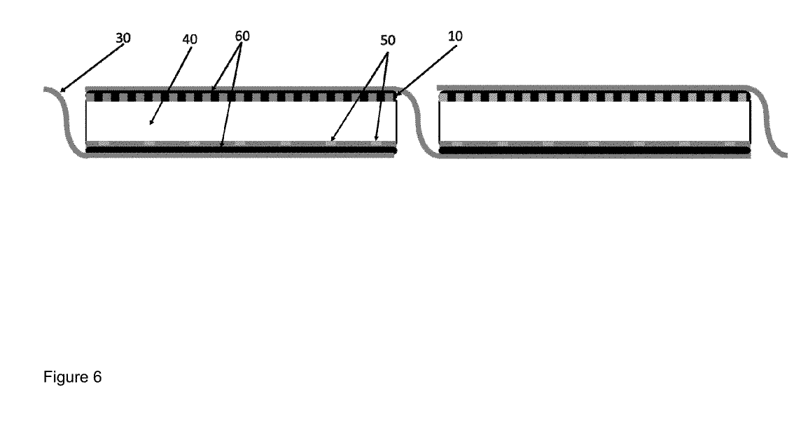

FIG. 6: shows two solar cells connected by a connector to form a photovoltaics module.

The object is met by a connector for connecting a solar cell electrode to a further element, whereby the connector comprises a conductor pattern on which at least one metallic coating is arranged, whereby the conductor pattern contains aluminium, characterised in that the coating contains an element selected from the group consisting of Ni, Ag, Sn, Pb, Zn, Bi, In, Sb, Co, Cr as well as alloys of said elements.

The connector according to the invention serves for electrical and mechanical connection of solar cell electrodes to a further element. The further element can be a connecting lead for a photovoltaics module or a further solar cell electrode. If the further element is a further solar cell electrode, the connector can be used to connect multiple solar cells in series to form a photovoltaics module. In order to ensure failure-free function of the photovoltaics module over the entire operating life, a mechanically robust and electrically conductive connection between the electrodes is required. The connection is exposed to various kinds of stress. For example, the connection between connector and solar cell electrode is exposed to varying temperatures during the manufacture or upon cyclic temperature changes during operation. The difference in thermal expansion coefficients of the materials involved leads to mechanical tension between solar cell electrode and connector. In addition, the cell connector is also exposed to corrosion, e.g. by oxidation, due, amongst other factors, to the flow of currents. The aforementioned stresses can cause the electrical and mechanical contact to the connector to decrease or fail completely over the useful life of the solar cell.

The connector comprises a conductor pattern, whereby the conductor pattern contains aluminium. Preferably, the conductor pattern consists of aluminium. In a further preferred embodiment, the conductor pattern can just as well contain an aluminium alloy or consist of an aluminium alloy.

In a preferred embodiment, the conductor pattern is a wire or a ribbon. Preferably, the aluminium wire can have a circular or oval cross-section. In case the conductor pattern is a ribbon, the preferred width is in the range of 200 μm-2 mm. The preferred thickness of the ribbon is in the range of 50 μm-350 μm. The preferred maximum diameter of the wire is in the range of 50 μm-350 μm.

At least one metallic coating is arranged on the conductor pattern. In a preferred embodiment, the surface of the conductor pattern is essentially fully covered by the metallic coating. Presently, “essentially fully” shall be understood to mean that the conductor pattern is covered in a firmly-bonded manner by the coating over the entire surface along the main axis. Said complete coating is also referred to as jacket or coating. In the context of the invention, the main axis of the conductor pattern shall be understood to be the axis along the longest extension of the conductor pattern. Preferably, the conductor pattern is open only on the ends such that the metallic coating is incomplete at the ends of the conductor pattern. In a further preferred embodiment, the coating can just as well fully cover the ends of the conductor pattern such that the entire circumference of the conductor pattern is enclosed. If the entire circumference of the conductor pattern is enclosed by a metallic coating, the conductor pattern is no longer accessible from outside.

In another preferred embodiment, the conductor pattern is not fully coated by a metallic coating along the circumference of the conductor pattern. In particular, it can be preferred to provide the conductor pattern with a metallic coating only in those places at which the contact to the electrodes of a solar cell will be established later. Said embodiment can save coating material and at the same time ensure that the contact surface is free of corrosion.

In order to be able to establish good contact between the aluminium-containing conductor pattern and the metallic coating, it is preferred for the conductor pattern to comprise no passivating oxide layer on the surface, such that metallic aluminium is present, if possible. A person skilled in the art is basically aware of how to attain an aluminium surface of the conductor pattern that is free of oxides, if possible. This can be attained, for example, by mechanical abrasion of material, plasma etching, galvanic reduction or chemical reduction. Optionally, the aforementioned procedures for removal of the oxide layer can be conducted in a protective gas atmosphere in order to prevent re-oxidation of the bare aluminium surface. The metallic coating can protect the conductor pattern from corrosion at acidic conditions. This allows the oxidation of aluminium to be prevented such that the electrical conductivity of the connector is maintained long-lastingly, in particular in the region of the contact surface to the solar cell electrode. Preferably, the thickness of the metallic coating is 10 nm-25 μm, in particular 0.1 μm-5 μm.

In a preferred embodiment, the metallic coating can contain an element selected from the group consisting of Ni, Ag, Sn, Pb, Zn, Bi, In, Sb, Co, Cr as well as alloys of said elements. Preferably, the metallic coating contains an alloy made of at least two of said elements. Particularly preferably, the coating contains at least one element selected from Ni, Ag, and Sn. Even more particularly preferably, the metallic coating fully consists of Ni, Ag or a SnPb alloy. In a preferred embodiment, the metallic coating is selected appropriately such that said coating does not produce an oxide layer on its surface even under acidic conditions (e.g. pH 4-6.5) such as can prevail in a photovoltaics module. An oxide-free surface on the connector according to the invention enables a durable, stable connection to solar cell electrodes. Specifically if the connector is being bonded to a solar cell electrode by means of an electrically conductive adhesive, it can be advantageous to have an oxide-free connector surface since this enables optimal adhesion.

The metallic coating can be applied by various known pathways. Preferably, the metallic coating can be applied by a procedure that is selected from the group consisting of immersion coating, chemical vapour phase deposition (CVD), physical vapour phase deposition (PVD), electrolytic deposition, printing, electroless plating, and roll cladding.

Presently, immersion coating shall be understood to be the immersion of a conductor pattern into a melt of a coating material. The melt is preferred to be a solder bath. In the scope of the invention, printing shall be understood to mean that a paste containing at least conductive metal particles and an organic medium is printed onto the aluminium conductor pattern and subsequently is affixed, e.g. by burn-in or sintering, while the organic medium evaporates.

In a further preferred embodiment, the conductor pattern can comprise more than one metallic coating. For example, a first metallic coating that inhibits and/or prevents the corrosion of the aluminium conductor pattern can be applied and a further metallic coating can be applied onto the first metallic coating in order to enable the connection to the solar cell electrode. The further metallic coating can, for example, be a solder coating.

Preferably, the metallic coating and/or the conductor pattern comprises a patterned surface (see, for example, FIG. 2) on the side exposed to sunlight. When a solar cell is assembled into a finished module, the module typically contains a protective layer over the solar cell that is aimed for protection from ambient influences. Said protective layer is preferred to be a glass layer. The pattern is designed appropriately such that incident sunlight is reflected appropriately by the connector such that it can effectively couple into the existing protective layer in a photovoltaics module (e.g. by internal total reflection) and does not escape from the photovoltaics module. By this means, sunlight reflected by the connector is made additionally available in the solar cell for the generation of charge carriers. The pattern can comprise a regular or an irregular pattern. For example, the pattern can comprise a regular sawtooth pattern of the type shown in FIG. 2. Regular patterns can be produced easily by embossing during the production of the connector.

In a preferred embodiment, the pattern contains pattern-forming elements with planar surface regions that are tilted by 20-40° with respect to the surface direction. Preferably, the distance of the peaks of two neighbouring pattern-forming elements (e.g. of two sawteeth) is in the range of 10 μm-500 μm, in particular in the range of 50 μm-300 μm, and particularly preferably in the range of 100-200 μm. As a result, incident sunlight can be reflected back efficiently into the solar cell.

In another preferred embodiment, the metallic coating and/or the conductor pattern comprises, on the side of the connector contacting the electrode, a pattern that enlarges the surface as compared to a planar surface (FIG. 4). Preferably, the surface is roughened by etching. Said pattern enlarging the surface can increase the mechanical adhesion between connector and solar cell electrode, in particular upon bonding with the aid of an electrically conductive adhesive.

Exemplary connectors are shown in FIG. 1. The sketched arrows each indicate the main axis of the connector. FIG. 1 shows two different embodiments, in which a conductor pattern (31) is surrounded by a metallic coating (32) along the main axis.

In one embodiment, the invention relates to a photovoltaics component comprising a solar cell, whose solar cell electrode is connected to a further element by means of a connector, whereby the connector comprises a conductor pattern on which at least one metallic coating is arranged and whereby the conductor pattern contains aluminium, characterised in that the coating contains an element selected from the group consisting of Ni, Ag, Sn, Pb, Zn, Bi, In, Sb, Co, Cr as well as alloys of said elements.

The solar cell electrode is arranged on a solar cell. A solar cell preferably contains at least one semiconductor substrate that is contacted by at least two solar cell electrodes of different polarity. The semiconductor substrate is preferred to be a doped silicon wafer. Preferably, the semiconductor substrate is a mono-crystalline or multi-crystalline silicon wafer. Preferably, the at least two solar cell electrodes comprise at least one rear electrode and at least one front electrode. In another embodiment, the at least two electrodes can just as well be arranged on the same side of the semiconductor substrate.

The rear electrode can be, for example, a metal layer applied to the surface. Preferably, said metal layer contains aluminium, in particular with contact regions made of silver. The front electrode is preferred to be a finger electrode or a busbar. A finger electrode shall be understood to be an electrode that is arranged on the solar cell in the form of a line that is several micrometers in thickness and serves to collect charge carriers, if possible, across the entire surfaces of the solar cell. Typically, a multitude of finger electrodes span the front side of a solar cell, in particular of a silicon solar cell. Preferably, the mean diameter of a finger electrode is in the range of 20-150 μm. A busbar typically connects multiple finger electrodes and serves to efficiently conduct away the current collected by the finger electrodes. Simultaneously, a busbar can serve to provide mechanically robust contact surfaces, e.g. for soldering. Preferably, a busbar has a larger wire cross-section than a finger electrode. The typical diameter of a busbar is in the range of 100 μm-2 mm and the height preferably is 1-20 μm. Preferably, a busbar comprises less adhesion to the semiconductor substrate then the finger electrodes it connects to each other.

In a preferred embodiment, a busbar is arranged additionally on a finger electrode. In a preferred embodiment, a busbar contacts multiple or all extant finger electrodes and the connector contacts at least one busbar.

In another preferred embodiment, the solar cell electrode consists of multiple finger electrodes, whereby the connector directly contacts at least one finger electrode. Accordingly, the connector can directly connect multiple finger electrodes to a further element without the finger electrodes being connected to each other by means of a busbar. Said embodiment is advantageous in that the production step for the busbar can be omitted, which simplifies the production.

Both the rear electrode and the front electrode are preferably produced by applying a conductive paste onto the semiconductor layer and then burning-in the applied conductive paste. The conductive paste can be applied onto the semiconductor layer by printing, such as, e.g., screen printing or stencil printing. A conductive paste typically comprises electrically conductive metal particles, a glass frit, and an organic medium. If the conductive paste is used for production of a rear paste, the electrically conductive metal particles preferably contain aluminium or consist of aluminium. If the conductive paste is used for production of a front paste, the electrically conductive metal particles preferably contain or consist of silver. Once the application is completed, the semiconductor substrate can be burned together with the conductive pastes applied to it to obtain the solar cell electrode. The organic medium can be removed by burning and a mechanically solid and electrically conductive electrode can be obtained. Accordingly, the solar cell electrodes thus obtained preferably comprise a mixture of glass and metal.

In the photovoltaics component according to the invention, the solar cell electrode is connected to a further element by means of a connector. Preferably, the further element is a further solar cell electrode of a solar cell. Particularly preferably, the further element is a further solar cell electrode of opposite polarity as compared to the first solar cell electrode. This means that a positive electrode on a first solar cell can be connected to a negative electrode on a further solar cell.

In a preferred embodiment, the contact between the solar cell electrode and the connector is an electrically conductive adhesive connection, a welding connection or a solder connection. Referring to a solder connection being established, the solder cannot be applied directly to the aluminium without generating an impeding oxide layer. However, a person skilled in the art is aware that aluminium components can be soldered with the aid of a thin intermediary layers (e.g. a layer of tin). The welding can preferably be ultrasound welding. The adhesive connection preferably consists of a thermosetting or thermoplastic polymer, in which conductive metal particles, in particular silver particles, are embedded.

In order to maintain a high conductivity of the contact of solar cell electrode and connector in the long term, it is particularly advantageous for the connector to comprise the largest possible contact surface to the solar cell electrode to be connected to it. In particular, the electrical contact is produced to be panel-like in this context. Panel-like shall be understood to mean that the connector is connected to the solar cell electrode over as much as possible of its entire projection perpendicular to the surface (70), as is shown in FIG. 3. (Arrow indicates the projection perpendicular to the surface of the solar cell).

The photovoltaics component according to the invention can be produced through the following steps:
a) Providing a solar cell comprising at least one solar cell electrode
b) Providing a further element
c) Connecting the solar cell electrode and the further element to the connector according to the invention.

The connection between the solar cell electrode and the connector and/or the connector and the further element in step c) can be established in a variety of ways. Preferably, the connection is established by bonding with an electrically conductive adhesive, by welding or by soldering. Preferably, the same procedure is used for connecting the connector to the solar cell electrode and for connecting the connector to the further element. Optionally, different procedures can be used for connecting the solar cell to the connector and for connecting the further elements to the connector.

The maximum temperature to which a solar cell, in particular a silicon solar cell, can be exposed is in the range of 750° C.-900° C. If the melting point of the material of the metallic coating on the connector is higher than said temperature range, the connector cannot be soldered or welded to the solar cell electrode, since these temperatures might destroy the solar cell. For example, nickel has a melting point of 1455° C., which is clearly higher than the acceptable temperature range for the solar cell. If a high temperature-melting metal such as nickel is to be connected to the solar cell electrode by means of soldering or welding, temperatures above the melting point that might destroy a solar cell would be required. In order to reduce the thermal stress, it can therefore be advantageous to establish the contacting of the solar cell electrode to the connector by means of a conductive adhesive that can be processed at room temperature or in the temperature range of up to 200° C.

In a preferred embodiment, the connection of the solar cell electrode and the connector and/or of the connector and the further element is established by means of an electrically conductive adhesive.

For example compositions containing a mixture of conductive metal particles and a polymeric adhesive system can be used as electrically conductive adhesives. The material of the conductive metal particles can be selected, for example, from copper, silver, nickel as well as alloys of said metals. Optionally, an electrically conductive adhesive can contain inorganic filling agents.

The polymeric adhesive system can be, for example, a curable adhesive system that has thermosetting properties after curing, i.e. a material that can no longer be deformed by heat after curing. Curing adhesive systems for electrically conductive adhesives are known to a person skilled in the art and can be selected to suit the requisite application. The curing can be initiated in a variety of ways. For example, the curing can be initiated chemically (i.e. by moisture), thermally or by light of a suitable wavelength. The electrically conductive adhesive can be, for example, a nickel particle- or silver particle-filled epoxy resin.

The polymeric adhesive system can be a self-curing one-component system or a two-component system. In a particularly preferred embodiment, the polymeric adhesive system is a UV-curable adhesive system. The curing is preferably attained by cross-linking of individual polymer chains into a contiguous network.

The electrically conductive adhesive can be applied by printing (i.e. screen printing or stencil printing). The electrically conductive adhesives can be applied either to the electrode to be connected or to the aluminium connector or both. The region that has electrically conductive adhesive printed on it is not limited to the electrode. After the solar cell electrode is contacted to the connector by means of the electrically conductive adhesive, the electrically conductive adhesive can be cured.

In an alternative embodiment, a double-sided adhesive film can be used that is introduced into the contact region between the solar cell electrode and the connector. In a preferred embodiment, the double-sided film is bonded onto the solar cell and then the aluminium connector is applied to the region that has the film bonded to it. Optimally, the film can be cured subsequently, i.e. by thermal treatment.

In a further alternative embodiment, the double-sided adhesive film can just as well be applied to the connector first and can then be contacted to the solar cell electrode.

The invention shall be illustrated in the following based on exemplary embodiments.

### Examples

### Provision of Solar Cells

A p-type cell with n-emitter from Q-Cells was used as a solar cell (resistance: 90 Ohm/square). The surface comprised a Si₃Nₓ antireflective coating on the front. The commercially available pace, Heraeus SOL 9631 C, was used to apply fingers and busbars to the front by means of screen printing. The line width of the fingers was 40 μm. Screen-printed silver solder pads were applied to the rear using the commercial available paste, Heraeus SOL205B. The aluminium BSF on the rear was printed by means of screen-printed commercial aluminium paste (RUX28K30, Guangzhou Ruxing Technology Development Co., Ltd. of Guangdong, China).

The pastes were dried and burned-in at a maximum temperature of 900° C.

### Coating

Multiple aluminium ribbons (1.5 mm in width, 300 μm in thickness) were provided with different metallic coatings.

Coating with silver:

The aluminium ribbon to be cladded was brushed, degreased and deoxidised on both sides in accordance with DIN 17611. The pre-treated aluminium ribbon was placed on a degreased and cleaned silver ribbon. In turn, the aluminium sheet was covered by a degreased and cleaned silver ribbon such that a so-called stack was produced.

The thickness of each layer was selected appropriately such that the ratio of layer thicknesses with respect to each other corresponded to the later target ratio in the rolled stack. The stack was assembled in the rolling gap of a cold roll cladding facility and was cold-pressure welded continuously at a high pressure to form a composite material. The stack was then temper rolled repeatedly and thereby reduced in thickness. The finished connector had a layer thickness of 300 μm, whereby the thickness of the coating was approximately 5 μm.

Coating with Nickel:

The aluminium ribbon to be cladded was brushed, degreased and deoxidised on both sides in accordance with DIN 17611. The pre-treated aluminium ribbon was placed on a degreased and cleaned nickel ribbon. In turn, the aluminium sheet was covered by a degreased and cleaned nickel ribbon such that a so-called stack was produced. The thickness of each layer was selected appropriately such that the ratio of layer thicknesses with respect to each other corresponded to the later target ratio in the rolled stack. The stack was assembled in the rolling gap of a cold roll cladding facility and was cold-pressure welded continuously at a high pressure to form a composite material. The stack was then temper rolled repeatedly and thereby reduced in thickness. The finished connector had a thickness of 300 μm, whereby the thickness of the nickel coating was approximately 5 μm.

Coating with Sn60Pb40

The aluminium ribbon to be cladded was brushed, degreased and deoxidised on both sides in accordance with DIN 17611. The pre-treated aluminium ribbon was placed on a degreased and cleaned Sn60Pb40 ribbon. In turn, the aluminium sheet was covered by a degreased and cleaned Sn60Pb40 ribbon such that a so-called stack was produced. The thickness of each layer was selected appropriately such that the ratio of layer thicknesses with respect to each other corresponded to the later target ratio in the rolled stack. The stack was assembled in the rolling gap of a cold roll cladding facility and was cold-pressure welded continuously at a high pressure to form a composite material. The stack was then temper rolled repeatedly and thereby reduced in thickness. The finished connector had a thickness of 300 μm, whereby the thickness of the nickel coating was approximately 5 μm.

### Bonding

A silver-containing conductive adhesive was applied per each busbar by stencil printing to the solar cell in the form of an adhesive strip of 1.5 mm in width and 150 mm in length. The amount of adhesive was 80 mg per solar cell (adhesive type, PC 4000, Heraeus). The aluminium connectors, previously coated with a metallic coating, were pushed onto the adhesive strip with a soldering table (Consol 2010, Somont GmbH, Germany). The adhesive was cured under pressure for 10 minutes at 150° C. on the soldering table.

### Ageing of the Samples

Two ageing tests were done on the solar cells thus produced:

a) Thermal ageing: After 48, 100, and 500 h exposed to air at 150° C. in a recirculating air drying cabinet, ten solar cells each were subjected to the electrical cell characterisation described below.
b) Climate chamber test: After 100, 500, and 1000 h exposed to 85° C. and 85% relative humidity in a recirculating air climate chamber (Vötsch VC0034, Germany), ten solar cells each were subjected to the electrical cell characterisation described below.

### Electrical Characterisation

The measurement of the fill factor (FF) of the sample before and after the aging tests was done with the cell tester “H.A.L.M. cetisPV-Celltest” (Halm Elektronik GmbH) at 25° C. The cell was irradiated with a Xe Arc lamp with a sunlight-like light spectrum with AM 1.5 at an intensity of 1000 W/m². The Halm IV tester utilises a multi-point contact for contacting for the detection of current (I) and voltage (V). In this context, the contact fingers of the measuring device are in direct contact with the busbars of the solar cell. The number of contact fingers is equivalent to the number of busbars. The detected electrical values were recorded and analysed by the device software. For reference, a calibrated standard solar cell (Fraunhofer Institute for Solar Energy Systems (ISE), Freiburg, Germany) of the same dimensions and the same wafer material was processed as described above and the electrical data obtained were compared to the certified values. Ten wafers were tested for each storage experiment and the median fill factor (FF) was calculated.

### Mechanical Characterisation

The pulling force (F) required to pull a connector according to the invention off a busbar was measured before and after ageing using a GP-Stab-Test-Pro device (GP Solar GmbH, Germany) at a pull-off angle of 45° C.

The connector was clammed in the test head and pulled off at a rate of 300 mm/min and at an angle of 45°. The pulling force thus determined was recorded from the curve and the minimum value, in Newton, was determined. The process was done on a total of 10 busbars and the median was determined. The results are summarised in Table 1.

TABLE 1

| | | | Pulling | | | Fill |
|---|---|---|---|---|---|---|
| | | | force F | | | factor |
| | | Pulling | (after | | Fill | (after |
| | | force F | climate | | factor | climate |
| | Pulling | (after | chamber | Fill | (after | chamber |
| Ribbon/ | force F | thermal | test | factor | thermal | test |
| coating | (before) | ageing) | 85°, 85%) | (before) | ageing) | 85°, 85%) |
| Al | + | −− | −− | + | − | − |
| Al/Ni | ++ | ++ | + | + | + | + |
| Al/ | + | + | + | + | + | + |
| Sn60Pb40 | | | | | | |
| Al/Ag | +++ | +++ | ++ | + | + | + |

1. A connector for connecting a solar cell electrode to a further element, whereby the connector comprises a conductor pattern on which at least one metallic coating is arranged, whereby the conductor pattern contains aluminium, characterised in that the coating contains an element selected from the group consisting of Ni, Ag, Sn, Pb, Zn, Bi, In, Sb, Co, Cr as well as alloys of said elements.

2. Connector according to claim 1, whereby the conductor pattern is a ribbon or a wire.

3. A photovoltaics component comprising a solar cell, whose solar cell electrode is connected to a further element by means of a connector, whereby the connector comprises a conductor pattern on which at least one metallic coating is arranged and whereby the conductor pattern contains aluminium, characterised in that the coating contains an element selected from the group consisting of Ni, Ag, Sn, Pb, Zn, Bi, In, Sb, Co, Cr as well as alloys of said elements.

4. Photovoltaics component according to claim 3, whereby the connector is connected to the solar cell electrode by means of an electrically conductive adhesive.

5. Photovoltaics component according to claim 3, whereby the solar cell electrode is a finger electrode or a busbar.

6. Photovoltaics component according to claim 1, whereby the connector directly contacts at least one finger electrode.

7. Photovoltaics component according to claim 3, whereby the metallic coating contains a pattern on the side on which the light is incident, whereby the pattern comprises pattern-forming elements with surface regions that are tilted by 20-40° relative to the direction of the surface.

8. Photovoltaics component according to claim 3, characterised in that the metallic coating comprises, on the side contacting the electrode, a pattern that increases the surface area as compared to a planar surface and is suitable for increasing the adhesion.

9. Photovoltaics component according to claim 3, whereby the further element is a further solar cell electrode.

10. Process for producing a photovoltaics component comprising the steps of
a. Providing a solar cell comprising at least one solar cell electrode
b. Providing a further element
c. Connecting the solar cell electrode and the further element by means of a connector according to claim 1.

11. Process according to claim 10, whereby, in step c), the connector is connected on the solar cell electrode by means of an electrically conductive adhesive.

12. Process according to claim 11, whereby the metallic coating is produced on the connector by means of a process that is selected from the group consisting of immersion coating, melt-coating, chemical vapour phase deposition (CVD), physical vapour phase deposition (PVD), electrolytic deposition, printing, electroless plating, and roll cladding.

13. Use of connectors according to claim 1 for connecting a solar cell electrode to a further element.
